(19) United States
(12) Patent Application Publication
(10) Pub. No.: US 2005/0151249 A1
(43) Pub. Date: Jul. 14, 2005

(54) Chip-size package with an integrated passive component

(76) Inventors: Gerald Eckstein, Munchen (DE); Anton Gebert, Kleinsendelbach (DE); Joseph Sauer, Strullendorf (DE); Jorg Zapf, Munchen (DE)

Correspondence Address: YOUNG & THOMPSON, 745 SOUTH 23RD STREET, 2ND FLOOR, ARLINGTON, VA, 22202, US

(21) Appl. No.: 10/502,713

(22) PCT Filed: Jan. 21, 2003
(86) PCT No.: PCT/DE03/00157

(30) Foreign Application Priority Data
Jan. 29, 2002 (DE) 102 03 397.8

(51) Int. Cl. H01L 23/48

(52) U.S. Cl. 257/737; 257/758; 257/528

(57) ABSTRACT

A passive component is integrated into a product having a rewiring location.

### CROSS REFERENCE TO RELATED APPLICATIONS

This application is based on and hereby claims priority to German Application No. 102 03 397.8 filed on Jan. 29, 2002, the contents of which are hereby incorporated by reference.

### BACKGROUND OF THE INVENTION

1. The Field of the Invention

The invention relates to a product and a method for fabricating a product.

2. Description of the Related Art

The trend in packaging and interconnection technology is resulting in ever smaller IC package designs. With the chip-size packages, the IC package is scarcely larger than the silicon area itself. Conversion of the bare chips to chip-size packages takes place at wafer level in the case of the most inexpensive method, wafer level packaging. With an additional insulating layer and a patterned metallization layer, the closely adjacent chip pads at the chip edges are planarly distributed on the chips in a grid.

The chip-size package is mounted on a wiring substrate and interconnected with passive components.

U.S. Pat. No. 6,025,647 discloses a product with a rewiring layer having an additional passive component.

### SUMMARY OF THE INVENTION

An object of the invention is to specify a product and a method for fabricating a product wherein the cost-intensive and space-consuming subsequent interconnection of the product with passive components on a wiring substrate can be dispensed with.

The product accordingly has contact pads. These product contact pads are used for contacting circuits contained in the product. On the product, preferably on at least one side of the product, there is disposed a rewiring layer.

The rewiring layer preferably includes at least one insulating layer and a patterned metallization layer. The insulating layer is built up on the product. Depending on the thickness of the insulating layer, the metallization layer—as a conductor level additively newly created on the insulating layer—lies on average 5 to 10 μm above the product (chip circuit).

A clear advantage is that, using this approach, the thickness of one or more, or all of the insulating layers can in each case be kept to less than 20 μm, more specifically to less than 10 μm. Typical layer thicknesses are even in the 5 μm range, thereby enabling a multilayer wiring substrate to be implemented in the form of a rewiring layer having a thickness in the 15 μm range or below.

In addition, the close proximity of metallization level and product and the building-up of the metallization layer on the product obviate the need for additional interconnection systems. By extending so far in, the metallization level is therefore connected to the product or product contact pads directly, i.e. without gluing, soldering or (wire) bonding.

The patterned metallization layer basically provides rewiring connections for contacting the product contact pads with rewiring contact pads. From these rewiring contact pads the product can be further contacted when it is mounted on a wiring substrate, e.g. a printed circuit board.

The rewiring layer further has, in addition to a rewiring connection, at least one passive component between at least one product contact pad and at least one rewiring contact pad. Essentially each rewiring connection, which can be implemented e.g. in the form of a rewiring conductor track, itself constitutes a passive component having a resistance, a capacitance and an inductance. The additional passive component is inserted over and above the rewiring connection in order to produce a required resistance, capacitance and/or inductance value, thereby obviating the need for subsequent interconnection with external passive components and for the components themselves, or else the number of components can be reduced.

The passive component contains a dielectric and/or a resistive material or is implemented thereby. Possible dielectrics are titanium oxide TiO₂ and/or tantalum oxide Ta₂O₃ which can be applied e.g. by a sputtering process and photolithographically patterned. Materials having an elevated resistance value compared to the specific resistance value of the rewiring material are preferably to be used as the resistive material.

The fabrication of the passive component can be very favorably integrated in the manufacturing process if the component is disposed between the product contact pad and/or rewiring contact pad on the one hand and the rewiring connection on the other, the most cost-effective solution being to dispose it between the product contact pad and the rewiring connection.

The passive component is preferably disposed within the rewiring layer to produce a particularly compact and easily mountable design.

The passive component can be a resistor, a capacitor and/or an inductor.

The product is more specifically a semiconductor device and/or a surface or bulk wave device in the form of a chip. The product and rewiring layer then together form a chip-size package.

In order to set the value of the passive component to a required value, the product contact pad and/or the rewiring contact pad can be at least partially covered by another insulating layer which only leaves a predefined size of contact pad opening.

A further or additional way of setting the value of the passive component consists in appropriately selecting the dielectric constant and/or the thickness of the dielectric or the thickness and/or the specific resistance value of the resistive material.

In addition to disposing it between contact pad and rewiring connection, the dielectric and/or the resistive material for implementing the passive component can also be disposed in a break in the rewiring connection. Here too options exist for setting a required value of the passive component, e.g. by the length of the break and/or by selecting the dielectric having a required dielectric constant and/or the resistive material having a required specific resistance.

Particularly for use in a chip-size package, the rewiring layer has a height of 3 to 30 μm.

A method for fabricating a product with a rewiring layer having a passive component as well as embodiments of the method will emerge accordingly from the described preferred embodiments of the product with the rewiring layer.

### BRIEF DESCRIPTION OF THE DRAWINGS

These and other objects and advantages of the present invention will become more apparent and more readily appreciated from the following description of an exemplary embodiment with reference to the accompanying drawings of which:

FIG. 1 is a cross sectional view of a product with a rewiring layer.

### DETAILED DESCRIPTION OF THE PREFERRED EMBODIMENT

Reference will now be made in detail to the preferred embodiments of the present invention, examples of which are illustrated in the accompanying drawings, wherein like reference numerals refer to like elements throughout.

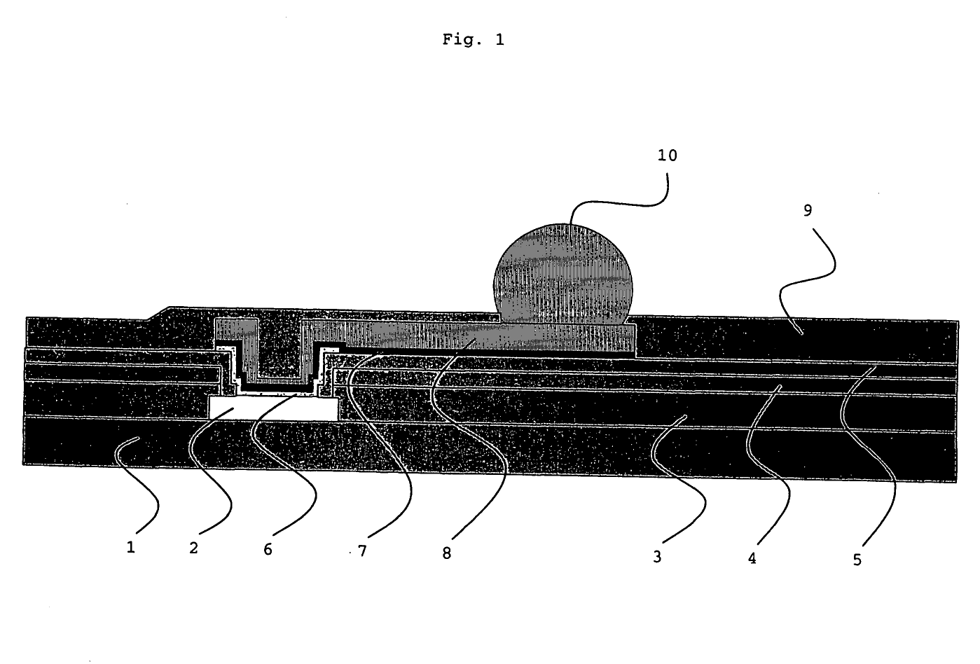

FIG. 1 shows a product 1 in the form of a silicon chip and having a product contact pad 2 in the form of an aluminum pad. In the area of the product 1 not covered by the product contact pad 2, it has on its surface a first passivation layer 3 of silicon nitrite (Si₃N₄) on which there is disposed a second passivation layer 4 of polyimide as an insulating layer. A layered structure of this kind is generally already produced in front-end operations.

The packaging process begins with the application of a passivation layer 5 in the form of another polyimide insulating layer on the wafer, the size of the further insulating layer 5 being set via the product contact pad 2 in order to control the value of the passive component to be incorporated in the rewiring layer, i.e. to determine the capacitance of an integrated capacitor, for example.

A suitable dielectric 6, e.g. titanium oxide or tantalum oxide, is then applied by sputtering or other suitable method and photolithographically patterned in such as way that is covers the product contact pad opening in the further insulating layer 5.

An adhesive layer 7 of e.g. titanium and copper is then applied in the region in which a rewiring connection will subsequently be created.

This is followed by another photolithographic patterning step for creating the rewiring connection 8 which is produced by electroplating e.g. with CuNiAu. Applied photoresist is then delayered and the superfluous titanium-copper areas are etched.

This is followed by the application of a fourth passivation layer 9 which again may be polyimide and can also be used as solder resist.

An opening is produced in the fourth passivation layer 9, preferably photolithographically, via the rewiring connection 8. A rewiring contact pad 10 in the form of a solder ball for contacting on a wiring substrate such as a printed circuit board is then produced by solder paste stencil printing and a reflow process.

In the example illustrated, a passive component essentially having a capacitance value and therefore functioning as a capacitor is implemented by the dielectric 6 between the product contact pad 2 on the one hand and the rewiring connection 8 on the other. The capacitance can be set by the size of the opening of the further insulating layer 5 above the product contact pad 2 and by the thickness and dielectric constant of the dielectric 6.

A passive component essentially having a resistance value and therefore functioning as a resistor can be implemented, for example, by a break in the rewiring connection. The resistance value can be varied by the length and width of the break in the rewiring connection as well as the thickness and specific resistance of the resistive material selected.

All in all, a passive component can be inexpensively incorporated in the rewiring layer by a single additional patterned layer.

The invention has been described in detail with particular reference to preferred embodiments thereof and examples, but it will be understood that variations and modifications can be effected within the spirit and scope of the invention.

1-10. (canceled)

11. A rewiring layer in a device having device contact pads, comprising:
rewiring contact pads;
rewiring connections between the device contact pads and said rewiring contact pads; and
at least one electrically passive component, formed of at least one of a dielectric and a resistive material, each separating at least one of said rewiring connections from at least one of the device and rewiring contact pads.

12. A rewiring layer according to claim 11, wherein said electrically passive component is one of a resistor, a capacitor and an inductor.

13. A rewiring layer according to claim 12, wherein the device is one of a semiconductor device, a surface wave device and a bulk wave device.

14. A rewiring layer according to claim 13, wherein said electrically passive component is formed of at least one of titanium oxide and tantalum oxide.

15. A rewiring layer according to claim 14, further comprising an insulating layer at least partially covering at least one of the device and rewiring contact pads and setting a value of said electrically passive component.

16. A rewiring layer according to claim 15, wherein the rewiring layer has a height of 3 μm to 30 μm.
